(19) United States
(12) Patent Application Publication
(10) Pub. No.: US 2011/0220590 A1
(43) Pub. Date: Sep. 15, 2011

(54) Temperature Adjustment of a Fluidic Sample within a Fluidic Device

(75) Inventor: Thomas Doerr, Waldbronn (DE)

(73) Assignee: AGILENT TECHNOLOGIES, INC., Santa Clara, CA (US)

(21) Appl. No.: 13/114,724

(22) Filed: May 24, 2011

Related U.S. Application Data
(63) Continuation of application No. 12/374,043, filed on Sep. 4, 2009.

(51) Int. Cl. G01N 1/44; B81B 7/00; G01N 30/30

(52) U.S. Cl. 210/774; 210/175

(57) ABSTRACT

A fluidic device configured for separating components of a fluid includes a flow path within an interior of the fluidic device, and at least one heatable frit positioned in the flow path and arranged to selectively adjust a temperature of the fluid in the flow path within the interior of the fluidic device.

This application is a continuation of co-pending U.S. application Ser. No. 12/374,043, filed 15 Jan. 2009, which is the National Stage of International Application No. PCT/EP2006/064309, filed on 17 Jul. 2006 which designated the United States of America, and which international application was published as Publication No. WO 2008/009311, both of which are incorporated by reference herein in their entirety.

### BACKGROUND

The present invention relates to a fluidic device for handling a fluidic sample.

In liquid chromatography, a fluidic analyte (e.g. a mobile phase comprising a sample to be analyzed in a solvent) may be pumped through a stationary phase (e.g. a column) comprising a material which is capable of separating different components of the fluidic analyte. Such a material, so-called beads which may comprise silica gel, may be filled into a column tube which may be connected to other elements (like a control unit, containers including sample and/or buffers) using fitting elements.

U.S. Pat. No. 5,908,552 discloses a column for capillary chromatographic separations, for example high performance liquid chromatography, including a column bed of packing material arranged in the inner bore of a column.

U.S. Pat. No. 5,858,241 discloses another column for capillary chromatographic separations.

US 2004/0156753 A1 by the same applicant, Agilent Technologies, discloses a polyacryl-ether-ketone based microfluidic device comprising two separate substrates which are bonded together to form channels where gases or liquids may move to accomplish applications of the microfluidic device. Thus, an internal cavity may be formed as a lumen or a channel of the microfluidic device.

During operation, a flow of sample traverses the column tube filled with the fluid separating material, and due to the physical interaction between the fluid separating material and the different components in the fluidic analyte, a separation of the different components may be achieved. Consequently, the fluid separating material filled in the column tube may be subject of a mechanical force generated by the fluidic analyte pumped from an upstream connection of the column to a downstream connection of the column with a relatively high pressure. Due to effects like friction, it may happen that a temperature profile is generated in the beads themselves and/or in the fluid being pumped through the separating material. Such a temperature profile may be formed in a direction perpendicular and in a direction parallel to the flowing direction of the sample and may have an impact on the performance of such a liquid chromatography device.

The dissertation of Gerhard Mayr (1999), University of Ulm, Germany, “Bildung and Kompensation von Temperaturgradienten in der schnellen HPLC unter Verwendung von Mikropartikel-gepackten HPLC-Saulen” (available via http://vts.uni-ulm.de/docs/1999/313/vts.sub.--313.pdf) discloses the formation and compensation of temperature gradients in a fast HPLC using microparticle packed HPLC columns.

Jeffrey R. Mazzeo, Uwe D. Neue, Marianna Kele, Robert S. Plumb, “A new separation technique takes advantage of sub-2-.mu.m porous particles”, Analytical Chemistry 467 A, December 2005 (available via http://pubs.acs.org/subscribe/journals/ancham-a/77/i23/pdf/1205feature_mazzeo.pdf), discloses that a radial thermal gradient may occur in a chromatography column, and that it is necessary to reduce the column diameter significantly to compensate for such thermal effect in columns packed with small particles.

### SUMMARY

It is an object of the invention to enable a proper performance of a fluidic device. The object is solved by the independent claims. Further embodiments are shown by the dependent claims.

According to an exemplary embodiment of the invention, a temperature control unit (for instance for adjusting a temperature with a thermal control effect selectively within the fluidic device) for a column of a fluidic device for analyzing a fluidic sample (a mobile phase, for instance a biochemical analyte) is provided, wherein the fluidic device is adapted to conduct the fluidic sample through the column, the temperature control unit being arranged to adjust a temperature of the fluidic sample (for instance by a thermal interaction with other components within the column) in a flow path between an inlet (for instance a position close to an inlet frit of a liquid chromatography apparatus) of the column and an outlet (for instance a position close to an outlet frit of a liquid chromatography apparatus) of the column so that a temperature adjustment effect occurs selectively in an interior of the column (particularly without a temperature adjustment before the fluidic sample enters and/or after the fluidic sample leaves the column).

According to another exemplary embodiment, a column (for instance a chromatographic column) for a fluidic device for analyzing a fluidic sample is provided, wherein the fluidic device is adapted to conduct the fluidic sample through the column, the column comprising a column tube and a temperature control unit having the above mentioned features arranged to adjust a temperature of the fluidic sample in a flow path between an inlet of the column tube and an outlet of the column tube so that a temperature adjustment effect occurs selectively in an interior of the column.

According to still another exemplary embodiment, a fluidic device (for instance a microfluidic device, for example a liquid chromatography apparatus) for analyzing a fluidic sample is provided, wherein the fluidic device is adapted to conduct the fluidic sample through a column, the fluidic device comprising a temperature control unit having the above mentioned features arranged to adjust a temperature of the fluidic sample in a flow path between an inlet of the column and an outlet of the column so that a temperature adjustment effect occurs selectively in an interior of the column.

According to yet another exemplary embodiment, a method of analyzing a fluidic sample is provided, the method comprising forcing the fluidic sample to flow through a column, and adjusting a temperature of the fluidic sample in a flow path between an inlet of the column and an outlet of the column so that a temperature adjustment effect occurs selectively in an interior of the column.

According to an exemplary embodiment, the temperature of a fluidic sample conducted through a column tube is selectively modified restricted to a spatial region between inlet and outlet of the column tube. By restricting the spatial range in which the heating (or cooling) effect occurs to the fluidic device to a portion between an inlet and an outlet of the column tube, the amount of heat to be transferred to achieve the temperature control may be reduced to a low value or a minimum. This may keep the required power consumption low and may further reduce or minimize the thermal stress acting on the fluidic sample which may include temperature sensitive components. Furthermore, such a spatially restricted heat injection mechanism may allow for an efficient and spatially limited control of the temperature. Effecting the temperature adjustment directly in an interior of the fluidic device may have the effect to not or not significantly contribute extra dispersing volume for high(est) chromatographical resolution.

Such a column internal heating (or cooling) procedure may be particularly implemented in the context of a liquid chromatography system (LC), with the result that no or only a minimum additional column volume is needed for heating. Consequently, the separation performance of the liquid chromatography system may be significantly improved.

Furthermore, controllable temperature gradients may be defined and generated in an interior of the tube in a fast, specific, directed and selective manner, and the spatial extension of the temperature control unit may be restricted to an interior of the column tube. Moreover, since only a very small volume has to be heated for such a temperature adjustment scheme, a fast analysis may become possible, since the dead time for stabilization of the system can be significantly reduced (for instance from conventionally 30 minutes to 2 minutes or less).

Furthermore, fast programmable temperature gradients may be implemented for modulating the elution power and viscosity within one analysis or from one analysis to the following one without additional wait or dead time of thermal equilibration. Therefore, the separation performance may be improved for a HPLC (High Performance Liquid Chromatography apparatus) or a HTLC (High Temperature Liquid Chromatography apparatus).

The technical setup for such a system may be such that a heat exchange procedure may be significantly shortened, since the temperature setting effect acting on the fluidic sample may be restricted to the portion between an inlet of the column (for instance a fitting or a frit) and an outlet of the column (for instance a further fitting or a further frit). For example, when the fluidic sample streams through the inlet frit (for example a metallic sinter body acting as some kind of filter as commonly used in LC devices), the frit itself may be the heating element so that a very small dead volume for heating or cooling the sample may be sufficient. For instance, such a frit may be heated inductively or may be heated with electromagnetic radiation, for instance infrared radiation. Any alternative thermal energy transfer scheme can be implemented so that a high energy supply or energy absorption may be carried out in a very short range. The heat control procedure may be performed during the flow through operation of a liquid chromatography device.

Therefore, the column tube may be heated from an interior, in a fast, selective, efficient and spatially limited manner. Therefore, a low dispersion solvent heating with a small dead volume may be made possible.

A reduced dead volume (“extra column volume”) as compared to capillaries through which the fluidic sample may be conducted before and/or after flowing through the column tube may be significantly achieved by a column-internal heating scheme. Commonly used is a metal-to-metal heat transfer (could be metal moulding or forced transfer from a hot metal structure to the capillary or other ways of heat transfer along the capillary) which inherently needs long fluidic path lengths to get the desired final temperature while increasing the undesired extra-column volume (deteriorating e.g. chromatographical resolution). Exemplary embodiments of the invention may involve only a very small “extra column volume” or even a “zero extra column volume”. Beyond this, according to an exemplary embodiment, disturbing dispersion effects may be suppressed when the heating occurs within a flow path of the fluidic sample between inlet and outlet of the column. In other words, the heating effect may be restricted to a spatial interval in which the fluid separation occurs.

For instance, foreign substances may be selectively inserted within the column tube which may then serve for heating. Such foreign substances may be mixed with fluid separation material (for instance powder or a monolithic column material, e.g. some kind of sintered silica instead of powder/particles) to assist during a column internal heat exchange mechanism. For instance, metal colloids may be inserted in the column tube together with beads and may serve as “secondary transformator coils” for interaction with electromagnetic radiation emitted by an external primary transformator coil. Additionally or alternatively to the metal colloids, a central rod (for example of metal) may be inserted into the column tube as some kind of antenna for absorbing inductively coupled electromagnetic radiation, serving as an energy carrier.

For instance, steel frits may be heated, for instance inductively and/or ohmically. Such frits may be sinter bodies usually provided at a beginning and at an end of the liquid chromatography column, acting as some kind of filters. It is also possible to provide larger frits than usual (to promote heat transfer), or to provide more frits, for instance 3, 4, 5 or 6 frits distributed along an extension of the column tube in accordance with a desired heating scheme.

The wall of the column tube may be made of a material which allows the entry of heat transporting agents, like a material being essentially transparent for radio frequency radiation, high frequency radiation, infrared radiation, etc. Ceramics tubes as an alternative to steel tubes are appropriate alternatives for specific applications.

Pre-heating a fluidic sample for fluid separation using a column may be made possible. A streaming medium may be heated immediately before and/or during separation in an essentially dead volume free manner. Therefore, the region for performing the heating may be defined to be downstream of an inlet of the column tube and upstream of an outlet of the column tube.

It is also possible to heat the packing material itself and/or the fluidic material, for instance making use of resonance absorption effect to selectively heat specific materials within the column tube. It is also possible to provide the column filling with additional materials (for instance colloids) which can be heated inductively. Alternatively, the fluid separating beads can also be used for heating.

Exemplary embodiments may be implemented in the context of a liquid chromatography device, but may also be used for gas chromatography, electrophoresis (particularly gel electrophoresis), etc.

The final temperature of the fluidic sample (before fluid separation starts) may be reached at the position at which the packing material begins, that is to say the temperature control may be performed between the insertion of the fluidic sample into the column tube and the starting of the fluid separation procedure.

According to an exemplary embodiment, a temperature within the volume of a column, for instance for liquid chromatography applications, may be adjusted (for instance increased or decreased or equilibrated) artificially by selectively and spatially dependently supplying or removing thermal energy.

When a fluidic sample to be analyzed is pumped through a column of a HPLC (High Performance Liquid Chromatography), an interaction between a moving component (namely the fluidic sample) and a static component (for instance fluid separation material, a stationary phase, in the form of beads filled in the column) may occur. Due to this interaction and due to an interaction between walls of a column tube and the streaming fluid, a temperature distribution occurs in a radial direction of a tubular column. Friction and other effects are described (for instance in Lauer, Sandra, “Influence of frictional heating on temperature gradients in ultra-high-pressure liquid chromatography on 2.1 mm I.D. columns”, Journal of Chromatography) to be the origin of such a temperature distribution. This may particularly have the consequence that fluidic sample flowing along a central or inner part of the column tube may have a larger velocity and temperature than fluid flowing closer to the inner walls of the column tube, that is to say in an outer portion of the cross-sectional area. As can be taken from a van Deemter plot, a temperature distribution along the cross-sectional area of the column may have the consequence that the fluid separation performance differs along the cross-sectional area. Thus, fractions or bands of components included in the fluidic sample to be separated may smear out, overlap, or may be broadened. Consequently, such a temperature distribution may deteriorate the fluid separation performance of a liquid chromatography apparatus. Exemplary embodiments may improve the performance of an LC apparatus by influencing the temperature characteristic inside of the column, which allows a specific modification of the temperature exactly in a spatial region which is essential for the obtainable fluid separation performance, namely the interior of the column where the fluid separating material is accommodated.

By taking this measure, the performance of a HPLC may be significantly improved. This may result in more narrow bands of fractions of a fluidic sample to be separated, and in a faster separation. Thus, accuracy and resolution of the fluid separation performance may be improved. However, exemplary embodiments are not restricted to liquid chromatography application, since a temperature dependent efficiency may also occur in other fields of fluidic devices, for instance in the field of gel electrophoresis. Also in this technical field, a temperature of a fluid separation material and a fluidic sample may have an impact on the mobility and/or thermally driven properties of components of an analyte, so that also in this technical field an adjustment of a temperature profile may be advantageous.

According to an exemplary embodiment, a temperature characteristic resulting from interactions between packing material for a column, walls of the column and fluidic sample to be pumped through the columns may be modified to be in accordance with a desired temperature characteristic. This may be performed in the context of a high performance liquid chromatography apparatus (HPLC apparatus).

A column may be used for separating different components of an analyte in a qualitative and/or quantitative manner, in order to identify components of a fluid. A packing material may separate the different components based on different affinities of the individual substances with respect to the column material. Therefore, the analyte may be pumped (for instance with a pressure of up to 2000 bar or more, or more generally with a pressure in which the fluid may become compressible) through the packing material for separation. The high pressure may further increase the problems with an undesired temperature characteristic, like temperature profiles along the radial and/or longitudinal direction of the column tube.

As beads, porous silica (silicon dioxide) may be used, for instance in a pulverized form, for instance with a particle size of 1.5 .mu.m to 10 .mu.m. Silica Gels may be used which may be baked under a high temperature to form porous spherical clusters. A dimension of a cluster may be 1.8 .mu.m with a component size of 0.01 .mu.m. Such a particle material may have an inner surface of the beads per mass unit of, for instance, 150 m.sup.2/g to 300 m.sup.2/g. The smaller the particle sizes, the stronger the interactions and therefore the friction between the beads and the fluidic sample, thus intensifying the temperature profile to be equilibrated according to an exemplary embodiment. Temperature control very near or in direct contact to the separation material may be particularly advantageous at relatively large cross-sectional areas of the column, like 1.0 mm, 2.0 mm, 3.5 mm, or 4.6 mm.

The packing material may comprise glass, polymeric powder, silicon dioxide, silica glass or monolithic structures based upon those base materials. However, any packing material can be used which has material properties allowing an analyte passing through this material to be separated into different components, for instance due to different kinds of interactions or affinities between fractions of the packing material and the analyte.

As an alternative to a conventional column packing material, planar silica microstructures and/or nanostructures may be used as a separation material. Such materials may be chemically modified to thereby adjust the separation/affinity properties. Such a technology may be an alternative to or a special embodiment of column technology. In this regard, a feature may be the control of the fluidic path length at each position of the separation. Also with such kind of devices, an integrated temperature control between an inlet and an outlet may be advantageous. Such a temperature control unit (like a heating unit) should have a low or zero contribution to the dispersion volume. Thus, such planar structures may be implemented in exemplary embodiments. Such ordered pillared structures have been studied by Fred Reginer or Peter Schoenmakers. Such structures may give an increase in the order of the packing and by controlling the interstitial spacing of the columns may also give a required porosity. With such materials, a temperature management (uniformity especially in a radial direction, but possibly also in a longitudinal direction) may then define the performance. By controlling the temperature between inlet and outlet, an intelligent energy insertion may be achieved. The term “column” may particularly cover fluidic devices having conventional beads as fluid separation material, but also solutions comprising planar silica microstructures and/or nanostructures, or similar materials as separation material.

According to an exemplary embodiment, control of temperature values and/or of temperature gradients within a packed particle bed of a HPLC column may be provided. Such a procedure may allow to resolve the supposed basic contradiction that friction heating within a packed bed of particles as occurring in pressure driven chromatography is lowering the viscosity in the column center thereby increasing the relative linear velocity in the center and at the same time having lower velocity and higher viscosity along the inner wall of the column enhanced by negative heat transfer through the column tube wall itself. The result of this may be bad chromatography by bad peak shape and chromatographical resolution caused by different parallel fluid streams in different parts of the bed. Especially the heat transient is a critical factor. By the thermal resistance of the column wall itself this leads to the challenge that, by indirect and unspecific heat control through the column wall no real in-situ control of the absolute inner fluid temperature and particularly of the radial temperature distribution within the packed particle bed is possible. According to an exemplary embodiment, a way to get rid of this basic constraint is to apply heat directly within the packed bed itself in a spatially dependent manner, favorable in a contactless way, so that the heat transfer and generation is part of the packed particle bed. For instance, this might be done by electromagnetic energy coupling as well from any power transformer application.

An obtainable benefit may be an improved heat distribution control which allows to work far beyond present high speed limitations therefore reaching new horizons of productivity and high speed analysis. This is already applicable and relevant starting from interior diameters of 1 mm (or less) to larger dimensions. An additional optional better control of the longitudinal temperature gradient may help to have generally lower viscosity delivering lower back pressure and therefore again higher achievable linear flow velocity and higher speed at higher resolution. An example for achieving that goal might be to wind a wire around the column tube (made of a non-metallic material like ceramics) as a primary inductance and to insert a spring-like secondary inductance (for instance any conductor, appropriate material, for instance, stainless steel) into the column tube which may be short-circuited to serve as a heating element and optionally guaranteeing wall touching by radial spring force. An embodiment is targeted to prevent and/or control inherent energy loss across the column wall, to smooth the radial gradient from center to wall and to further use columns with relatively large interior dimensions with all related advantages like method compatibility or minimal changes thereof.

According to an exemplary embodiment, it may be possible to control the temperature along any desired direction of the column, thereby having the possibility to obtain a desired temperature distribution, or a homogeneous temperature. Any technical feature may be provided having an effect selectively within an interior of the column for locally controlling the temperature of the fluid to be separated. Therefore, a local control of the temperature and the column in a direction differing from the flowing direction and/or in the flowing direction itself may be made possible.

One possible option may be to flatten the radial temperature gradient which is believed to be caused by interior friction within the bed of the packed liquid chromatography column. This effect may become particularly relevant with a particle size of less than 2 .mu.m, an inner column diameter (ID) of 1 mm or more, and generally also with increased pressure and very high flowing rates. However, an even more important aspect of exemplary embodiments may be a small or even zero dispersion in-column heating.

There are many possibilities of adjusting such a temperature profile or, more generally, of influencing the temperature properties specifically in an interior of the column tube. The temperature profile may be controlled in a contactless manner, or in a contact-bound manner. The term “contactless” may particularly denote that the provision of thermal energy may be performed without a (direct) mechanical or electrical contact between such an energy delivering unit and the material filled within the interior of the column. An example for a contactless method is an inductive or capacitive coupling from an exterior of the column into an interior of the column so as to deposit energy within an interior of the column. The term “contact-bound” may particularly denote that the temperature is supplied or removed with a direct thermal contact (like a mechanical connection) allowing a thermal equilibration between the material filled in the column tube and the unit for supplying/removing the energy. An example for a contact-bound method is a heating wire supplied within the column for a direct thermal contact with the material to be heated or direct ohmic heating of an inlet frit.

Exemplary solutions are providing or removing heat by convection procedures or by directly heating from an exterior of the column. It is possible to heat the fluidic sample and/or the fluid separation material and/or to heat particles (for instance metal colloids) which may be selectively inserted into the column bed to support contactless heating particularly by (for instance resonantly) absorbing electromagnetic waves.

With respect to the technical setup of such columns, sufficiently thin steel or ceramic tubes may enable a punctual supply of energy to the critical column inner wall in order to generate a desired temperature characteristic.

According to one embodiment, a limited penetration depth of energy (for instance in the form of electromagnetic waves) into the column bed may be used (for instance infrared absorption, high-frequency absorption and/or interaction with polar solvents, for instance water, dipole-dipole interactions, Van der Waals interactions, etc.) to define a spatial dependency as to how to deliver heat. Such effects may be used particularly for the contactless energy transfer through the glass, ceramic and/or metal tube.

According to another exemplary embodiment, any suitable impurities may be selectively inserted (for instance with a statistical distribution) into the column bed which, by contactless energy transfer, may manipulate the temperature in a desired manner. Appropriate shapes of impurities are powder materials, granulates, spiral springs, rods or a heating tube within the column tube (for instance a heated intermediate wall).

Not only a temperature profile along a radial direction of the tube may occur, but also in a longitudinal flowing direction of the fluidic sample. A “longitudinal gradient” may have the consequence that the separation at the end of the column may be faster as compared to the separation at the beginning of the column. When the column is tempered in an undesired manner (for instance equal temperature), the column wall may be colder as compared to the core at a portion close to the end of the column, which may smear out the fractions to be separated. This negative influence on the performance of the fluidic device may be suppressed or eliminated by varying the energy transfer along the longitudinal direction of the column.

Thereby, by compensating a temperature profile along a cross-section and/or along a longitudinal direction of the column tube, the local temperature distribution within the tube may be equilibrated so that disturbing effects like parallel column fractions or a superposition of peaks related to different fractions of the sample may be avoided or at least suppressed.

Compensating a temperature profile may allow for a temperature management specifically and selectively within the column, thereby spatially narrowing a volume which is to be thermally controlled.

According to an exemplary embodiment, a programmable and essentially delay-free temperature gradient may be generated by an active control of the thermal heat distribution in a column tube (“zero” dispersion heating). It may be made possible according to exemplary embodiments to obtain an essentially immediate temperature modification in contrast to a very long time for a heat equilibration. Exemplary embodiments may be implemented in the context of HTLC (High Temperature Liquid Chromatography, that is an LC apparatus operating at temperatures larger or significantly larger than 60 .degree. C., up to 200 .degree. C. and more) and “green” chemistry. At high temperatures, the polarity of the solvent may be modified such that it may be possible to carry out separations using water, which separations are otherwise only possible with organic solvents. In other words, separations can be carried out dynamically not only using different solvents of different polarity, but also with different temperature during an analysis.

It is also possible to define a desired time-dependency of a temperature distribution (or a homogeneous temperature value) which is desired in the column, for example during a user-specific experiment to be carried out. The temperature control unit may then control the column internal temperature so that the desired time-dependency of the temperature distribution is made possible. For this purpose, the fluidic device may comprise a user interface to allow such a user-defined temperature control.

According to an exemplary embodiment, an essentially dead volume free heating and/or an essentially delay-free heating may be made possible when using the column input frits as heating elements themselves by contactless (e.g. inductive heating) or contact heating (applying a current across a very low ohmic frit resistance). Those frits may be mandatory parts of each column to hold back the packing material while being adjusted or optimized for reduced or minimum band spreading. A typical approach is to use a sintered stainless steel metal dust with a controlled pore size.

According to an exemplary embodiment, it is possible to combine a high performance with high pressures and flow through volumes. As a fluid separation material, silica gel beads or polymers may be used, for instance with dimensions between 5 .mu.m and 3.5 .mu.m. So-called “sub-two-.mu.m” beads having a dimension of less than 2 .mu.m may allow to obtain an even better separation performance and a better dispersion characteristic. The described fluid separation materials may be appropriate even for very high temperature applications.

Embodiments of the invention may be implemented in the context of liquid chromatography apparatus, particularly of a High Performance Liquid Chromatography (HPLC). For fluid separation, the fluidic sample is pumped through the arrangement with a high pressure (of larger than 200 bar, up to 1000 bar and more). A separation may occur in accordance with a chemical interaction between beads and the components of the fluidic sample (in accordance with affinities). Therefore, different retention times for the different fractions may result in a separation. The separated fractions may then be detected (e.g. read out), preferably optically (for instance using physical parameters like absorption or fluorescence properties), or using a mass spectroscopy device.

The smaller the particles in an LC column, the larger is the resistance of the column with respect to fluidic sample. The smaller the beads and the larger the pressure, this interaction increases. With a so-called “rapid resolution LC”, a high resolution per time may be obtained.

As beads, silica gel with baked 10 nm particles may be used, so that beads in an order of magnitude or 1.8 .mu.m, 3.5 .mu.m, 5 .mu.m, or 10 .mu.m may be generated. It is also possible to attach functional groups to the beads so as to promote a desired affinity.

With respect to the fluid separation techniques, particularly two aspects may be distinguished. A preparative separation may be implemented for a purification of a sample. An analytic separation may be used for detection which components are present in an unknown sample under examination.

As can be taken from a van Deemter diagram as shown in FIG. 1 and which will be described below in more detail, a small bead particle size may increase the performance of an LC apparatus, wherein an optimum velocity value increases. Beyond this, the van Deemter curves are temperature dependent, wherein again a further improved or optimum velocity value increases the fluid separation performance therefore allowing higher speed analysis with same resolution in general. High radial temperature gradients within the column instead will result in bad peak shape and low resolution by facts described already above. As indicated by the van Deemter plot, small particles result in a flat curve, large temperatures result in a flat curve, and especially a radial temperature profile may result in a broadening of the peaks. Such a radial temperature profile may deteriorate the performance of an LC.

By reducing the temperature gradient by supplying or removing energy in a spatially dependent manner from the efficient column cross-section, a high degree of flexibility and a high level of performance may be obtained.

Such a radial temperature gradient and/or a longitudinal temperature gradient may result from friction between column wall and fluidic sample. This generates a velocity profile. This velocity profile results in a temperature profile by friction between the fluidic sample and the beads/the solvent.

The temperature management may be obtained by heating an interior wall of the column tube.

As exemplary appropriate column tube wall materials, stainless steel, ceramics, quartz, glass, or other appropriate materials may be used. The wall thickness can be few millimeters to obtain both a high degree of mechanical stability and the possibility to efficiently introduce heat into the system.

For adjusting the way of heating, benefit can be taken of the properties of the solvent, the fluid separation material, the fluidic sample, and the wall material of the column. The wall, for instance, may be used as an active heating element. Alternatively, ultrasonic sound, microwaves, high-frequency radiation, an inductive coupling of energy, etc. may be used. For instance, an annular microwave emitter may be attached at an outside of the column tube. When the wall of the column tube is manufactured from a microwave transmitting material, the microwaves are absorbed by the fluidic sample, wherein a penetration depth of the system for microwaves may be taken into account. When using infrared radiation, the infrared absorption properties of fluid separation material and/or solvent and/or fluidic device may be used, wherein resonance effects may be used advantageously.

It is also possible to provide an ohmic heating attached to and/or integrated in the wall of the column. An inductive or capacitive coupling may also be implemented for thermal power supply. For this purpose, a primary and a secondary transformator coil may be used for introducing heat in a contactless manner into an interior of the column tube. When using induction for supplying thermal energy, metal rings may be heated integrated in or attached to an interior wall of the column tube. Spiral springs which may be short circuited and which may be, optionally, foreseen with a gradient of the winding number per length along the longitudinal axis of the column tube, may be provided. Short circuiting a secondary winding, the electric energy can be transformed into thermal energy, for selectively heating outer portions of the fluid stream.

It is also possible to position a rod (or the like) centrally within the column, wherein such a central rod may serve as a heat sink for guiding or for leading off thermal energy from the hot core of the fluidic sample stream to an outside of the column, like to a heat consumer or a cold reservoir. The rod may be warmed by being brought in contact with column beads and/or a mobile phase for a sufficiently long time. An actively remove of heat may be possible as well. Providing a rod in a central portion may reduce the distance between centrally located beads and beads located close to the wall of the column tube, which may suppress the generation of an intensive radial temperature gradient, in a similar manner as in small column tubes having an inner diameter of less than, for instance, 2 mm. The rod can also be used for an active heating.

Therefore, a thermal manipulation of the fluidic sample may be performed so as to adjust the temperature profile of the analyte. Thus, by actively influencing the thermal properties of the wall, the active manipulation or the temperature properties may be made possible.

Next, further exemplary embodiments will be explained. In the following, further exemplary embodiments of the temperature control unit for a fluidic device/a column/a column tube will be explained. However, these embodiments also apply for the column, for the fluidic device and for the method.

The temperature control unit may be arranged to adjust the temperature so that the temperature adjustment effect occurs only or exclusively in an interior of the column. In other words, the interaction between the energy generating or dissipating unit and the fluidic sample occurs at a position at which the fluidic sample is within the column. The thermal manipulation area may therefore be restricted to the spatial interval between column inlet and column outlet. In contrast to this, according to this embodiment, essentially no thermal manipulation occurs in the fluid path before the inlet and after the outlet. Low dispersion cooling or lowest dispersion cooling may be reasonable at the end of the column, for instance to avoid stress acting on a subsequent detection. Such a temperature control at an end of the column, close to the outlet, or even slightly behind or downstream of the outlet may be covered by a temperature control unit according to an exemplary embodiment as well.

The temperature control unit may further be arranged to adjust the temperature so that the temperature adjustment effect does not occur before the fluidic sample enters the inlet of the column. Particularly, the portion before the fluidic sample enters a fitting or a frit of the column tube may be free of any temperature influencing measure.

The temperature control unit may be arranged to heat the fluidic sample selectively in an interior of the column. Thus, the heating procedure may occur within the for instance cylindrically shaped column tube.

At least a part of the temperature control unit may be located within an interior of the column to heat the fluidic sample in the interior of the column. By this spatially close localization between temperature increase or decrease unit and material to be heated, the spatial resolution or accuracy in providing or removing energy may be further increased.

The temperature control unit may be adapted to heat the fluidic sample in the flow path between the inlet of the column and the outlet of the column. This portion may be the only spatial part in which the heating effect occurs. Advantageously, the heating procedure may be completed at the moment at which the fluidic sample enters the fluid separation material. For instance, only a frit provided at an entrance of the fluidic device may be the heating element.

The temperature control unit may be adapted to be arranged at least partially inside the column. However, at least another part of the temperature control unit may be adapted to be arranged outside the column. For instance, when heating inductively, the primary transformator coil may be located outside, for instance surrounding, the column tube, wherein the secondary transformator coil absorbing electromagnetic energy emitted by the primary coil may be located within the column tube and therefore in essentially direct thermal conduct with the material to be heated.

The temperature control unit may be adapted to adjust the temperature using at least one mechanism of the group consisting of heat conduction, heat convection and heat radiation. The term “heat conduction” may be denoted as the transmission of heat across a material, via a continuous mechanical path. The term “heat convection” may be denoted as the transfer of heat by currents within a fluid (wherein the term fluid may here denote a gas and/or a liquid). It may arise from temperature differences within the fluid or between the fluid and its boundary. The term “heat radiation” may be denoted as the only form of heat transfer that can occur in the absence of any form of medium and as such is the only way of heat transfer through a vacuum. Thermal radiation may be a direct result of the emission of electromagnetic radiation, which carries energy away from the surface. Furthermore, when a surface is bombarded by electromagnetic radiation from the surroundings, this may also result in the transfer of energy to the surface.

In the following, further exemplary embodiments of the column of a fluidic device will be explained. However, these embodiments also apply for the temperature control unit, for the fluidic device and for the method.

The temperature control unit may be adapted for selectively providing energy to at least one material of the group consisting of the fluidic sample, a fluid separating material filled in at least a part of the column tube, and electromagnetic radiation absorbing particles, particularly metallic particles, filled in at least a part of the column tube. For instance, it is possible to heat one or more of these components, wherein effects like heat conduction may then heat the fluidic device being brought in interaction with one of the described components.

The temperature control unit may comprise a thermal energy source for providing thermal energy to the fluidic sample in the column tube. It may be advantageous to heat an interior of the column tube, because the performance of an LC apparatus may be improved at high temperatures by higher resolution per time.

The thermal energy source may comprise a heating wire wound in at least one manner of the group consisting of being wound along an inner surface of the column tube, being wound along an outer surface of the column tube, and being accommodated in an interior of the column tube. An AC current or a DC current may be applied to the heating wire. The heating wire may have a spiral shape or may also have the shape of a hollow cylinder lined along an inner surface of the tube. Electric current can be injected into one or a plurality of portions along the extension of the column tube, wherein the latter embodiment allows a more accurate definition of the temperature profile compensation. It is also possible that the heating wire(s) has or have an essentially straight geometry.

The thermal energy source may comprise a heating fluid stream generating element for generating a hot fluid stream to be brought in thermal contact with the column tube. For instance, blowing hot air in defined manner to an outer surface of the column tube may allow to heat the column tube in a defined manner, wherein by heat conduction at least a part of this energy may be transferred into the fluidic sample. It is also possible to provide some kind of hollow cylindrical structure within the column tube through which hollow cylindrical structure a hot air or a hot liquid stream may be passed to be brought in thermal interaction with the fluidic sample so as to adjust the temperature.

The thermal energy source may also comprise an electromagnetic radiation generation unit for generating electromagnetic radiation. Such electromagnetic radiation may have any desired wavelength, like radio frequency (RF), microwaves, infrared, optical light, ultraviolet light, or X-rays. The absorption characteristics of the different electromagnetic radiation frequency ranges may be taken into account. Furthermore, radioactive sources (like an .alpha.-emitter, a .beta.-emitter or a .gamma.-emitter) may be used for heating.

The thermal energy source may further comprise an ultrasound generation unit for generating ultrasound radiation. The absorption of ultrasound radiation, that is to say mechanical waves, may also heat the sample in a defined manner, so that a desired temperature profile can be adjusted.

The thermal energy source may comprise a primary inductive coupling element (which may be located outside of the tube) for providing an alternating electrical signal and may comprise a secondary inductive coupling element located attached to or integrated in the column tube and inductively coupled to the primary inductive coupling element. The coupling scheme may be, as an alternative to a pure inductive coupling, be also a pure capacitive coupling or a mixed inductive and capacitive coupling. For instance, a coil may be arranged to surround the column, and within the material of the column or at an outer or inner wall surface of the column, a secondary coil may be provided. The secondary coil may be short-circuited so that inductions currents generated in the secondary coil may be transformed into heat which may then be used to equilibrate the temperature profile. This secondary inductive coupling element may comprise one or a plurality of metal rings located at or in the column tube, or a metal coil located at or in the column tube. It is also possible to use, as a secondary inductive element, a thin-walled hollow cylinder of a metallic material. The metal rings located along a longitudinal direction of the column may vary in thickness, length or ohmic resistance so that, by varying these geometry parameters, the heat transfer may be adjusted along an extension of the column.

The column tube may comprise a first portion adapted to be coupled to a first fitting element adapted for fitting the column tube to another element upstream a fluid path. Furthermore, the column may comprise a first frit element located in the first portion and adapted to adjust the temperature of the fluidic sample. Therefore, the first frit element may be heated, for instance in an ohmic manner or in an inductive manner, so that when flowing through the heated frit element (for instance a metallic sinter body for filtering the fluidic sample), the fluidic sample may be brought to a desired temperature. Then, the entire fluid separation procedure may be carried out at an essentially constant temperature, because this temperature adjustment has been performed beforehand.

The column tube may comprise a second portion adapted to be coupled to a second fitting element adapted for fitting the column tube to another element downstream a fluid path. Furthermore, the column may comprise a second frit element located in the second portion and adapted to adjust the temperature of the fluidic sample. For instance, it may be desired to modify the temperature again at a position at which the fluidic sample leaves the column tube. Therefore, such an end frit may be used for further heating or cooling the fluidic sample.

The fluidic sample may be adapted to flow along a first direction of the column tube, for instance along a central direction of the column tube. The temperature control unit may be adapted to at least partially compensate a temperature profile in the column along a second direction which differs from the first direction. For instance, a temperature profile extending in a cross-sectional area of the column tube which is essentially perpendicular to the flowing direction of the fluidic sample may conventionally deteriorate the performance of the LC apparatus, since such a temperature profile with a usually hot core and a colder environment may be interpreted as a plurality of parallel fluid fractions which have different fluid separation properties. Due to such a temperature profile, the resolution of the separated components (the different bands of fractions) may be deteriorated, or accuracy may be deteriorated. In order to compensate such a temperature profile, the temperature control unit may adjust the temperature of the fluidic sample in a spatially dependent manner in such a plane perpendicular to the flowing direction. Therefore, disturbing temperature profiles may be at least partially equilibrated.

At least a part of the column tube may be filled with a fluid separating material. Such a fluid separating material may be silica gel, carbide, polymers, etc. The fluid separating material may have the effect to separate different fractions of the fluidic sample due to the different affinity between the fluid separating material and the fluidic sample.

At least a part of the column tube may be filled with a fluid separating material which comprises beads having a size in the range of essentially 1 .mu.m to essentially 50 .mu.m. Thus, these beads may be small particles which may be filled inside the column.

At least a part of the column may be filled with a fluid separating material comprising beads having pores of a size in the range of essentially 0.02 .mu.m to essentially 0.03 .mu.m (porous material) or non-porous material. The fluidic sample may interact by pores and/or modified surfaces of porous or non-porous materials, wherein an interaction may occur between the fluidic sample and the pores. By such effects, separation of the fluid may occur.

The temperature control unit may comprise a thermal energy sink for absorbing thermal energy from components of the fluidic sample in dependence of a distance of a component from a center of the column tube. As already mentioned above, as an alternative to supplying energy, it is also possible to selectively thermally de-energize parts of the column filling. Such a thermal energy sink may be adapted for absorbing more thermal energy from components of the fluidic sample which are located closer to the center of the column as compared to components of the fluidic sample which are located further away from the center of the column tube. For instance, a thermally conductive wire with a large heat capacity may be provided along the center of the column and may be thermally coupled to a cooling bath located outside of the column, for instance an ice bath. This may selectively absorb energy from the portion of the filling of the column which is hottest, namely the central portion.

The column tube may comprise at least one of the material group consisting of steel, ceramics, quartz and glass and other materials. The material of the column tube may be adjusted to the specific way of supplying and/or absorbing energy. For instance, when energy shall be supplied from outside, a material with a low thermal resistance may be used.

In the following, further exemplary embodiments of the fluidic device will be explained. However, these embodiments also apply for the temperature control unit, for the column and for the method.

The fluidic device may comprise a sensor for measuring the temperature in the fluidic device. Furthermore, a regulator unit may be provided for regulating the temperature control unit to adjust the temperature in the column of the fluidic device based on a measurement performed by the sensor. Therefore, a feedback loop may be implemented, in which the actual temperature profile may be measured and, as a result of this measurement, the mode of supplying thermal energy to the system may be increased, reduced, or the spatial dependence of the heat supply may be adjusted or regulated. The measurement of the temperature profile may occur, for instance, using any one or more dimensional (for instance array-like) temperature sensor which may measure the (spatial dependence of the) temperature distribution within the column in a contact-bound or contactless manner.

The fluidic device may be adapted as a fluid separation system for separating components of the fluidic sample. When a fluidic sample is pumped through the fluidic device, preferably with a high pressure, the interaction between a filling of the column and the fluidic sample may allow for separating different components of the sample, as performed in a liquid chromatography device or a gel electrophoresis device.

However, the fluidic device may also be adapted as a fluid purification system for purifying the fluidic sample. By spatially separating different fractions of the fluidic sample, a multi-component sample may be purified, for instance a protein solution. When a protein solution has been prepared in a biochemical lab, it may still comprise a plurality of components. If, for instance, only a single protein of this multi-component liquid is desired, the sample may be forced to pass the column. Due to the different interaction of the different protein fractions with the filling of the column (for instance using a gel electrophoresis device or a liquid chromatography device), the different samples may be distinguished, and one sample or band of material may be selectively removed as a purified sample.

The fluidic device may further be adapted to analyze at least one physical, chemical or biological parameter of at least one component of the fluidic sample. The term “physical parameter” may particularly denote a size or a temperature of the fluid. The term “chemical parameter” may particularly denote a concentration of a fraction of the analyte, an affinity parameter, or the like. The term “biological parameter” may particularly denote a concentration of a protein, a gene or the like in a biochemical solution, a biological activity of a component, etc.

The fluidic device may comprise at least one of the group consisting of a sensor device, a test device for testing a device under test or a substance, a device for chemical, biological and/or pharmaceutical analysis, a capillary electrophoresis device, a liquid chromatography device, a gas chromatography device, an electronic measurement device, and a mass spectroscopy device. Particularly, the fluidic device may be a High Performance Liquid Chromatography device (HPLC) in which different fractions of an analyte may be separated, examined and analyzed.

The fluidic device may be adapted as microfluidic device. The term “microfluidic device” may particularly denote a fluidic device as described herein which allows to convey fluid through micropores, that is pores having a dimension in the order of magnitude of micrometers or less.

The fluidic device may be adapted to conduct the fluidic sample in the fluidic device with a high pressure, particularly a pressure of more than 100 bar, more particularly of more than 200 bar, for instance with essentially 400 bar, particularly of at least 500 bar or more, for instance up to 1000 bar.

### BRIEF DESCRIPTION OF THE DRAWINGS

Other objects and many of the attendant advantages of embodiments of the present invention will be readily appreciated and become better understood by reference to the following more detailed description of embodiments in connection with the accompanied drawings. Features that are substantially or functionally equal or similar will be referred to by the same reference signs.

FIG. 1 shows a van Deemter plot.

FIG. 2 and FIG. 3 show fluidic devices comprising temperature control units according to exemplary embodiments of the invention.

FIG. 4 to FIG. 10 show temperature control units according to exemplary embodiments.

The illustration in the drawing is schematically.

### DETAILED DESCRIPTION

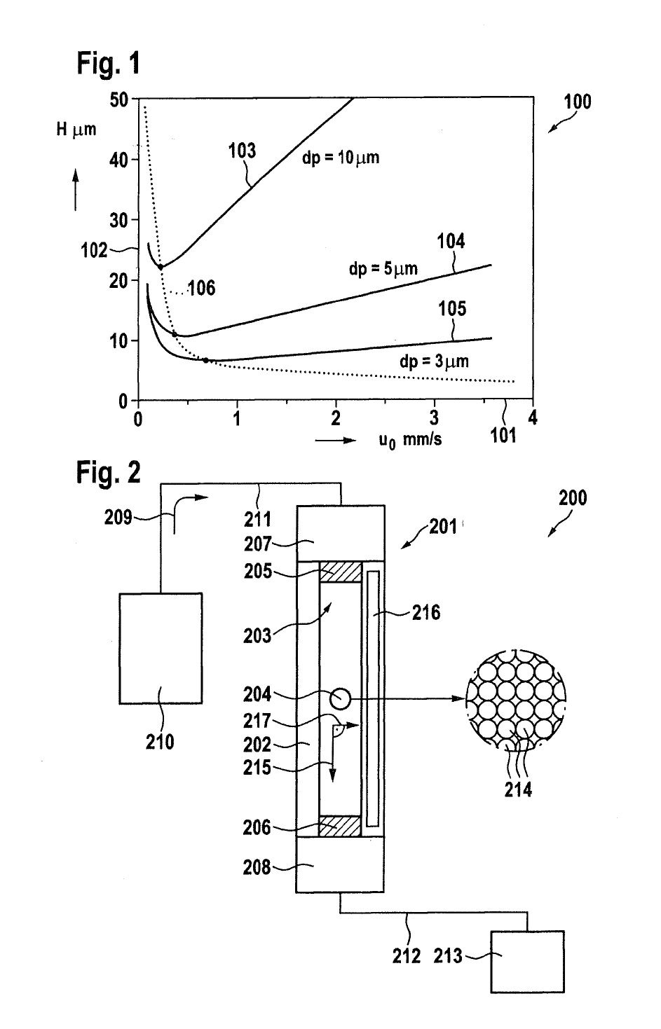

In the following, referring to FIG. 1, a van Deemter plot 100 will be explained to provide some background information about the effects which are used by exemplary embodiments and to explain recognitions one which exemplary embodiments are based.

The van Deemter diagram 100 in FIG. 1 comprises an abscissa 101 along which the velocity of a fluidic sample to be transported through a column is plotted in mm/s. Along an ordinate 102 of the diagram 100, the so-called plate height H is plotted in .mu.m, which is a measure for the separation performance, that is to say for the efficiency of separating the fluidic sample into different fractions. Thus, a separation performance, efficiency or resolution is plotted along the ordinate 102.

In a first curve 103, a dependency is shown for beads (as fluid separating material) with a size of 10 .mu.m. A second curve 104 is related to beads with a size of 5 .mu.m, and a third curve 105 is associated to fluid separation particles with a size of 3 . mu.m.

Furthermore, FIG. 1 shows a fourth curve 106 which is formed by connecting the minima of the curves 103 to 105 (and of other curved for other bead sizes). The curve 106 illustrates a respective optimum operation condition for best resolution per time for the respective particle size.

The column pressure increases inversely with the particle size square. The velocity at the minimum of the curves 103 to 105 increases with the inverse of the particle size. The column pressure and the minimum of the van Deemter curves 103 to 105 increases with inverse of the cubic power of particle size.

FIG. 1 indicates a relationship between the linear interstitial velocity plotted along the abscissa 101 and the separation performance plotted along the ordinate 102. However, the van Deemter curves 103 to 105 are also temperature dependent. Therefore, when the temperature varies along a cross-section of an LC tube, the separation performance H plotted along an ordinate 102 changes as well for the different portions with different velocities and temperatures.

In the light of the foregoing, exemplary embodiments intend to at least partially control the temperature of the fluidic sample flowing between an inlet and an outlet of the column tube.

In the following, referring to FIG. 2, a fluidic device 200 according to an exemplary embodiment will be explained.

The fluidic device 200 is adapted as a system for carrying out liquid chromatography investigations. The fluidic device 200 for separating different components of a fluid which can be pumped through the apparatus 200 comprises a column 201 having a column tube 202 which is shaped as a hollow cylinder. Within this cylinder, a tubular reception 203 is defined which is filled with a package composition 204.

The fluidic device 200 is adapted as a liquid chromatography device comprising a first frit 205 close to an inlet 207 of the column 201 and a second frit 206 provided at an outlet 208 of the column 201. A first fitting element 207 forms the inlet and is provided upstream the column tube 202. A second fitting element 208 forms the outlet and is located downstream of the column tube 202. A flowing direction of fluid which is separated using the fluidic device 200 is denoted with reference numeral 209.

A fluid separation control unit 210 is provided which pumps fluid under pressure of, for instance, 200 bar through a connection tube 211 and from there through the fitting element 207 and the first frit 205 into the column tube 202. After having left the column tube 202, that is to say after having passed the second frit 206 and the second fitting element 208, a second tube or pipe 212 transports the separated analyte to a container and analysis unit 213. The container and analysis unit 213 includes cavities or containers for receiving different components of the fluid, and may also fulfil computational functions related to the analysis of the separated components.

The column tube 202 comprises the filling 204. In other words, a packing composition 204 comprising a plurality of silica gel beads 214 is inserted into the hollow bore 203 of the column tube 202.

The fluidic device 200 is adapted for analyzing a fluidic sample, and is adapted to conduct the fluidic sample along a first direction 215, namely a longitudinal direction of the fluid flow, in the fluidic device 200.

The fluidic device 200 comprises a temperature control unit 216 (which is plotted only schematically in FIG. 2) to adjust a temperature of the fluidic sample in a flow path between an inlet 207 of the column 201 and an outlet 208 of the column 201 so that temperature adjustment effect occurs selectively in an interior of the column 201.

Furthermore, a second direction 217 which is essentially perpendicular to the first direction 215 and lies in a plane perpendicular to the first direction 215 is plotted. It is optionally possible to adjust a temperature profile along a direction 217, which, for instance may occur due to the friction between the fluidic device and inner walls of the column tube 202.

The temperature control unit 216 is arranged to adjust the temperature so that the temperature adjustment effect occurs only in an interior of the column 201. In other words, no temperature controlling effect occurs in the tubes 211 and 212. In contrast to this, the temperature of the fluidic sample is adjusted selectively and exclusively only in the portion between inlet 207 and outlet 208.

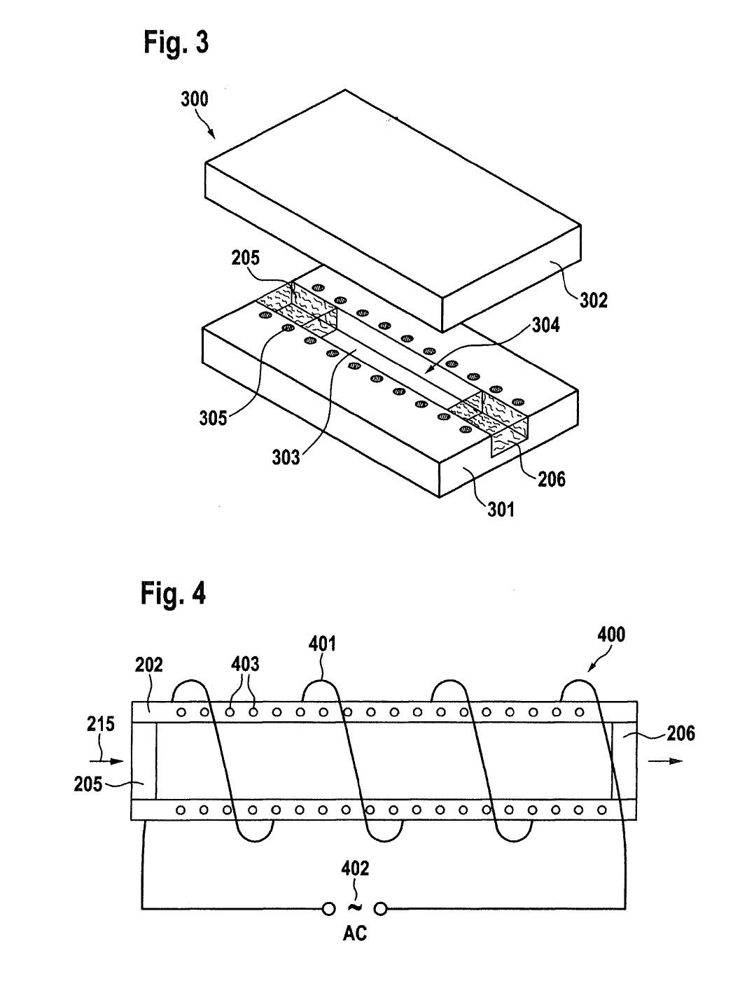

Before a plurality of different embodiments for the temperature control unit 216 will be described in more detail referring to FIG. 4 to FIG. 9, reference is made to the fluidic device 300 shown in FIG. 3.

Referring to FIG. 3, a microfluidic device 300 according to an exemplary embodiment will be described.

The microfluidic device 300 comprises a first essentially planar member 301 and a second essentially planar member 302. In an operation state in which the first essentially planar member 301 is coupled to the second essentially planar member 302 (for instance using a glue connection), a column tube is formed by a recess 303 which is formed in the first essentially planar member 301 and by the planar surface of the second essentially planar member 302. The recess 303 forms, when the members 301 and 302 are connected to one another, a channel-like structure which has a similar function like the inner bore 203 of the column tube 202 of FIG. 2.

The microfluidic device 300 can be used in a similar manner as described in FIGS. 6a, 6b and corresponding description of US 2004/0156753 A1.

FIG. 3 illustrates a patterned Polyacryletherketone substrate 301 having the internal cavity 303 and the other flat surface 302 that can be bonded with the patterned Polyacryletherketone substrate 301 to form the microfluidic device 300. The flat substrate 302 can be formed by any solvent resistant material, including, but not limited to, Polyacryletherketone or glass. The patterned Polyacryletherketone substrate 301 can be formed using any fabrication technique, including embossing, laser ablation, injection moulding, etc. It should be further understood that the microfluidic device 300 can include multiple channels 303, and each channel 303 can include a packing composition with a fluid separation material.

As shown in FIG. 3, the channel 303 comprises a central portion which may be filled with fluid separating material, like silica beads. Furthermore, a first frit 205 and a second frit 206 are shown. The fluid separating beads may be inserted into a central portion 304 of the recess 303, that is to say in the entire portion of the recess 303 which remains when the frits 205, 206 are inserted in the end portions of the recess 303.

In order to control a temperature distribution within the channel 303, a secondary induction coil 305 is formed embedded in the first substrate 301 and (although not shown in FIG. 3) correspondingly formed in the second substrate 302. When the first substrate 301 is connected to the second substrate 302, the electrically conducting structures 305 form a common spiral in the interior of which the channel 303 is housed. When an external coil (not shown in FIG. 3) carrying alternating electric current is provided, and when such a primary coil is inductively coupled to the secondary coil 305, induction currents are generated in the (short circuited) secondary coil 305 which are transformed into ohmic heat. This ohmic heat may then influence or modify the temperature of material filled in the channel 303. Furthermore, the frits 205 and 206 made of a metallic sinter material may support the temperature control function. When the primary coil has such a geometrical extension that induction currents are generated also in the frits 205, 206, these frits may support the heating of the fluidic sample. The primary coil and the secondary coil 305 may be considered to form a kind of transformator. The winding distance may be adjusted or optimized for compensating the longitudinal heating process which may lead to non-linear distances between the windings.

FIG. 4 to FIG. 10 which will be explained in the following show exemplary embodiments of a temperature control unit capable of adjusting a temperature of the fluidic sample in a flow path between an inlet and an outlet of a column so that a temperature adjustment effect occurs selectively in an interior of the column.

In the embodiment of FIG. 4, a temperature control unit 400 is shown which is adapted as a thermal energy source for selectively supplying thermal energy to material in the interior of the column tube 202. The thermal energy source of the temperature control unit 400 comprises a primary inductive coupling element 401, namely a primary coil wound around the outside of the column tube 202 and adapted for providing, using a current source 402, an alternating electrical signal. In other words, an alternating current (AC) is generated by the current source 402 and is supplied to the primary coil 401.

Furthermore, the temperature control unit 400 comprises a secondary inductive coupling element 403, namely a current source embedded in an interior of the column tube 202, which is an integrated metal coil. When an alternating current is supplied to the primary coil 401, the transformator principle generates a secondary current in the secondary coil 403 (and also in the frits 205 and 206 made of a metallic sinter material) which is transferred into ohmic heat. This ohmic heat may be supplied to an interior of the column tube 202 to selectively heat material contained herein. Particularly, the inlet frit 205 may automatically heat the fluidic sample entering the channel 304.

A thermal energy reflection element may be provided in the column tube 202 outside of the secondary coil 503 so as to reflect any thermal radiation or the like which propagates towards the outside of the column tube 202. Such radiation may be reflected back to contribute to the heating of an interior of the tube 202. Particularly, portions along an outer diameter of the interior of the column tube 202 are heated predominantly, since the distance between the generation of the heat at the secondary coupling 503 in these outer portions is smaller than a distance between the secondary coil 503 and an interior of the column tube 202 (that is to say a portion located adjacent to a symmetry axis of the column tube 202).

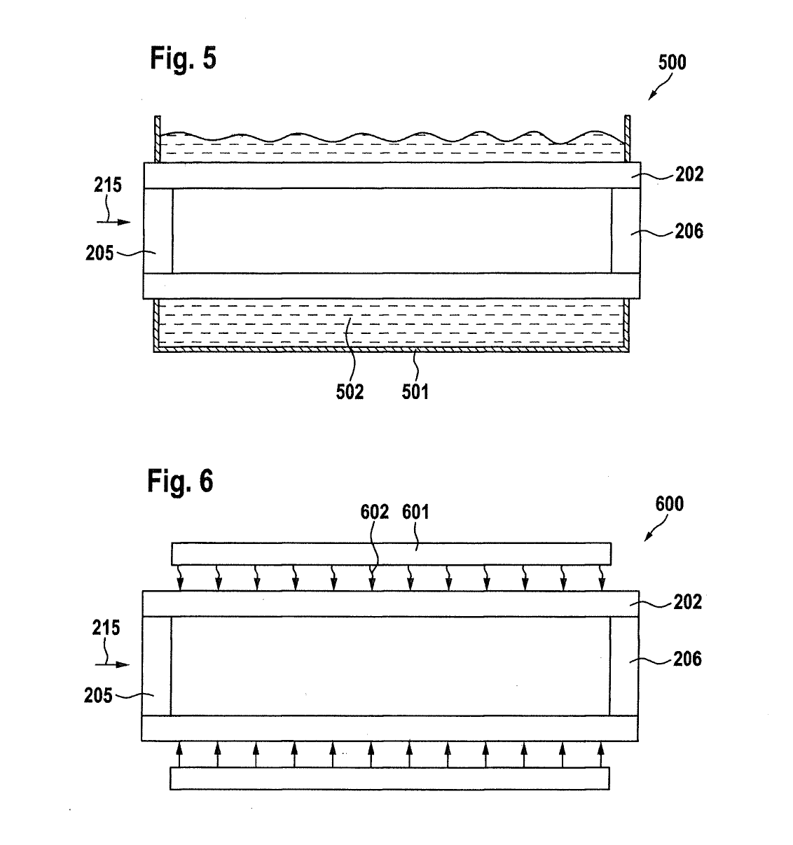

In the following, referring to FIG. 5, a temperature control unit 500 according to an exemplary embodiment will be explained.

In the embodiment of FIG. 5, a container 501 is provided in which the portion between the first frit 205 and the second frit 206 of the column tube 202 is dipped or immersed. Within the container 501, a heating fluid 502 is provided which surrounds an outer circumference of the column tube 202, and which may be a thermally well-conducting material. The heating fluid 502 may also serve as a cooling fluid and may be an immersion heater or a boiling device. Therefore, a selective supply of thermal energy to outer portions of an interior of the column tube 202 may be ensured.

In the following, referring to FIG. 6, a temperature control unit 600 according to an exemplary embodiment will be explained.

In the embodiment of FIG. 6, the column tube 202 is surrounded by a hollow cylindrically shaped electromagnetic radiation source 601 adapted to generate electromagnetic radiation 602 of an adjustable wavelength. The electromagnetic radiation 602 is adapted to transmit the electromagnetic radiation 602 to the column tube 202 to be absorbed predominantly by circumferentially outer portions of a fluidic sample flowing in direction 215 through an interior bore of the column tube 202. For instance, the wavelength may be in the infrared, ultraviolet or microwave frequency region, wherein the selection of the wavelength may influence the penetration depth of the radiation into the cylindrical fluid sample body. Thus, adjusting the wavelength and/or intensity of the radiation may allow to be used as a design parameter for controlling the thermal energy transfer to thereby equilibrate a temperature profile.

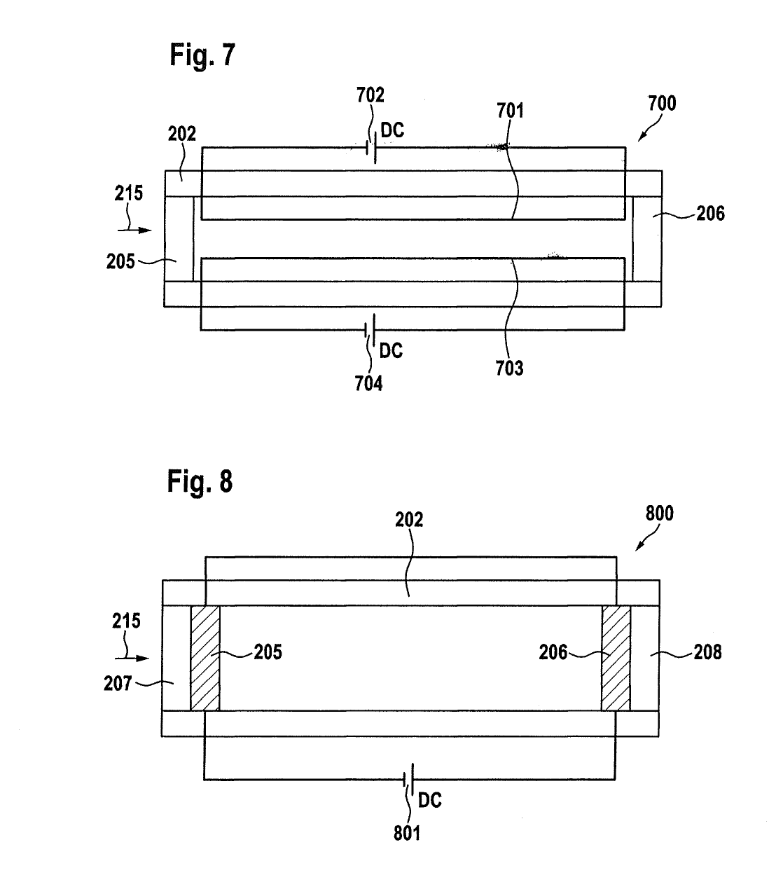

In the following, referring to FIG. 7, an exemplary embodiment of a temperature control unit 700 will be explained.

The temperature control unit 700 comprises a first heating wire 701 connected to a first direct current (DC) source 702 and comprises a second heating wire 703 connected to a second direct current source 704. Although only two heating wires 701, 703 as shown in FIG. 7, a plurality of such heating wires may be provided along an outer circumference of the interior of the cylindrical column tube 202. Therefore, thermal energy is supplied along a circumference of the outer diameter of the bore of the column tube 202 so as to selectively heat outer portions of the fluidic sample. As an alternative, only a single heating wire may be provided, or a heating hollow cylinder which may be fed with an electrical current may be provided. The electrical current generates ohmic heat which then is transmitted to the fluidic sample.

In the following, referring to FIG. 8, a temperature control unit 800 according to an exemplary embodiment will be explained.

As can be seen in FIG. 8, a direct current source 801 is connected to the two metal frits 205, 206 so that a direct current is fed by the current source 801 to the relatively high ohmic metal frits 205, 206. Therefore, the frits 205, 206 are heated, and when fluidic sample is pumped along a direction 215 through the column tube 202, a heat exchange between the fluidic sample and the heated frits 205, 206 occurs, so that a heating between the fitting elements 207, 208 may be made possible. According to an exemplary embodiment, the heating element (in the present embodiment the frits 205, 206) may or may not be in physical contact with the packing material in the column tube 202. Such a heating element may also be formed by the fitting element(s) 207, 208 of the column, additionally or alternatively to the heating via the frit(s) 205, 206. Even an element (like a heating frit) which is located close or directly in front of an inlet of a column tube may be used for a temperature control unit according to an exemplary embodiment.

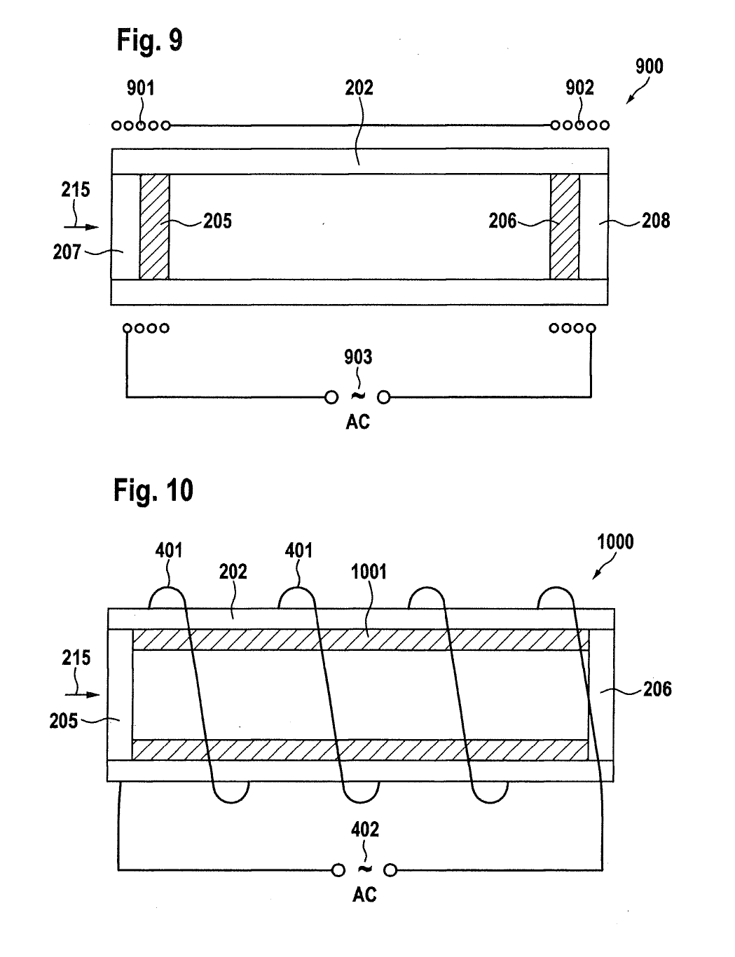

In the following, referring to FIG. 9, a temperature control unit 900 according to an exemplary embodiment will be explained.

In the embodiment of FIG. 9, coils 901, 902 which are fed by an alternating current source 903 serve as primary induction coils for a transformator, wherein the metallic frits 205, 206 serve as secondary coils and heat fluidic sample pumped along a direction 215 due to the ohmic heat generated when electromagnetic radiation is transformed from the primary coils 901, 902 into the secondary frit coils 205, 206.

In the following, referring to FIG. 10, an exemplary embodiment of a temperature control unit 1000 will be explained.

The embodiment of FIG. 10 is similar to the embodiment of FIG. 4. However, the temperature control unit 1000 uses a “tube-in-tube” architecture in which an electrically conductive inner tube 1001 is located within an electrically insulating outer tube 202. By applying an alternating voltage (using the voltage supply unit 402) to a coil 401 surrounding both tubes 202, 1001, an exterior inductive heating of the electrically conductive inner tube 1001 is possible (the electrically conductive inner tube 1001 may therefore be considered as one secondary winding).

It should be noted that the term “comprising” does not exclude other elements or features and the “a” or “an” does not exclude a plurality. Also elements described in association with different embodiments may be combined. It should also be noted that reference signs in the claims shall not be construed as limiting the scope of the claims.

1. A fluidic device configured for separating components of a fluid comprising:
a flow path within an interior of the fluidic device; and
at least one heatable frit positioned in the flow path and arranged to selectively adjust a temperature of the fluid in the flow path within the interior of the fluidic device.

2. The fluidic device of claim 1, wherein the at least one heatable frit is configured to be heated by contactless heating.

3. The fluidic device of claim 2, wherein the at least one heatable frit is configured to be heated by induction.

4. The fluidic device of claim 1, wherein the at least one heatable frit is configured to be heated by contact-bound heating.

5. The fluidic device of claim 4, wherein the at least one heatable frit is configured to be heated by directly applying a current.

6. The fluidic device of claim 1, further comprising a temperature controller for controlling the temperature of the at least one heatable frit.

7. The fluidic device of claim 1, further comprising an inlet and an outlet and at least a first of the heatable frits proximate the inlet.

8. The fluidic device of claim 7, further comprising:
at least a second of the heatable frits positioned proximate the outlet; and
a temperature controller for controlling the temperature of the heatable frits to provide a temperature gradient in a particular direction within the interior of the fluidic device.

9. A method of separating components of a fluid within a fluidic device comprising:
providing a flow path within an interior of the fluidic device; and
selectively adjusting a temperature of the fluid in the flow path within the interior of the fluidic device using a heatable frit.

10. The method of claim 9, comprising heating the heatable frit by contactless heating.

11. The method of claim 10, comprising heating the heatable frit by induction.

12. The method of claim 9, comprising heating the heatable frit by contact-bound heating.

13. The method of claim 12, comprising heating the heatable frit by directly applying a current.

14. The method of claim 9, comprising controlling the temperature of the at least one heatable frit by using a temperature controller.

15. The method of claim 9, further comprising
positioning at least a first of the heatable frits proximate an inlet of the fluidic device;
positioning at least a second of the heatable frits proximate an outlet of the fluidic device; and
using a temperature controller for controlling the temperature of the heatable frits to provide a temperature gradient in a particular direction within the interior of the fluidic device.
